(19) United States
(12) Patent Application Publication
(10) Pub. No.: US 2008/0160759 A1
(43) Pub. Date: Jul. 3, 2008

(54) Method for fabricating landing plug contact in semiconductor device

(75) Inventors: Min-Suk Lee, Kyoungki-do (KR); Jae-Young Lee, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(73) Assignee: Hynix Semiconductor Inc.

(21) Appl. No.: 11/824,218

(22) Filed: Jun. 29, 2007

(30) Foreign Application Priority Data
Dec. 27, 2006 (KR) 2006-0134258

(51) Int. Cl. H01L 21/44

(52) U.S. Cl. 438/672

(57) ABSTRACT

A method for fabricating a semiconductor device includes forming an etch barrier layer over a semi-finished substrate that includes a plurality of patterns, forming an insulation layer over the etch barrier layer, planarizing the insulation layer, recessing a portion of the planarized insulation layer, forming a hard mask pattern over the recessed and planarized insulation layer, etching the recessed insulation layer to form a contact hole, etching the etch barrier layer formed over a bottom portion of the contact hole, and forming a plug contact in the contact hole.

### CROSS-REFERENCE TO RELATED APPLICATIONS

The present invention claims priority of Korean patent application number 10-2006-0134258, filed on Dec. 27, 2006, which is incorporated by reference in its entirety.

### BACKGROUND OF THE INVENTION

The present invention relates to a method for fabricating a semiconductor device, and more particularly, to a method for fabricating a semiconductor device including a landing plug contact.

Landing plug contact (LPC) technology has been applied in a semiconductor fabrication process to improve the scale of integration. The landing plug contact is often formed in a trench type or a bar type structure. The bar type landing plug contact is used in highly integrated semiconductor devices from 0.16 μm level to 60 nm level.

The bar type landing plug contact generally requires performing an isolation process using a subsequent chemical mechanical polish (CMP) process. Thus, a thickness of a gate hard mask often needed in a self-aligned contact (SAC) process becomes large.

The thickness of the gate hard mask for defining a 60 nm level semiconductor device is approximately 2,200 Å or greater. The thickness of the gate hard mask increases to fabricate a device smaller than 60 nm level. Accordingly, an aspect ratio substantially increases. It is difficult to secure a stable dynamic random access memory (DRAM) fabrication process because a contact defining ability having high aspect ratio is generally needed. Also, because forming such contact includes performing the SAC process which generates a large amount of polymers, the process becomes even more difficult due to an increase in the size of an etch target.

The aforementioned limitations also occur during a bit line contact process or a storage node contact process using a SAC process.

### SUMMARY OF THE INVENTION

Embodiments of the present invention are directed to a method for fabricating a semiconductor device, which can limit the increase in the size of an etch target that would otherwise be caused by a high aspect ratio during a contact formation process that uses a self-aligned contact process.

In accordance with an aspect of the present invention, there is provided a method for fabricating a semiconductor device, including: forming an etch barrier layer over a semi-finished substrate that includes a plurality of patterns; forming an insulation layer over the etch barrier layer; planarizing the insulation layer; recessing a portion of the planarized insulation layer; forming a hard mask pattern over the recessed and planarized insulation layer; etching the recessed insulation layer to form a contact hole; etching the etch barrier layer formed over a bottom portion of the contact hole; and forming a plug contact in the contact hole.

### BRIEF DESCRIPTION OF THE DRAWINGS

FIGS. 1A to 1G illustrate cross-sectional views of a method for fabricating a semiconductor device in accordance with a first embodiment of the present invention.

FIGS. 2A to 2I illustrate cross-sectional views of a method for fabricating a semiconductor device in accordance with a second embodiment of the present invention.

### DESCRIPTION OF SPECIFIC EMBODIMENTS

Embodiments of the present invention relate to a method for fabricating a landing plug contact in a semiconductor device. According to the embodiments of the present invention, a thickness of an insulation layer needed during a landing plug contact etch process is reduced. Such decreased thickness allows a decrease in an aspect ratio, resulting in a reduced-size etch target and prevention of undesirable events in a device, such as a not-open event.

Furthermore, the reduced-size etch target of the insulation layer decreases a loss of a gate hard mask during a self-aligned contact (SAC) etch process. Thus, a height of the gate hard mask may be additionally decreased, and consequently, a height of the gate patterns may be decreased.

Moreover, processes for forming additional insulation layers such as a silicon oxynitride (SiON) layer and a plasma enhanced tetraethyl orthosilicate (PETEOS) layer may be omitted. Such layers are generally formed for patterning when using an amorphous carbon hard mask. Thus, the process may be simplified.

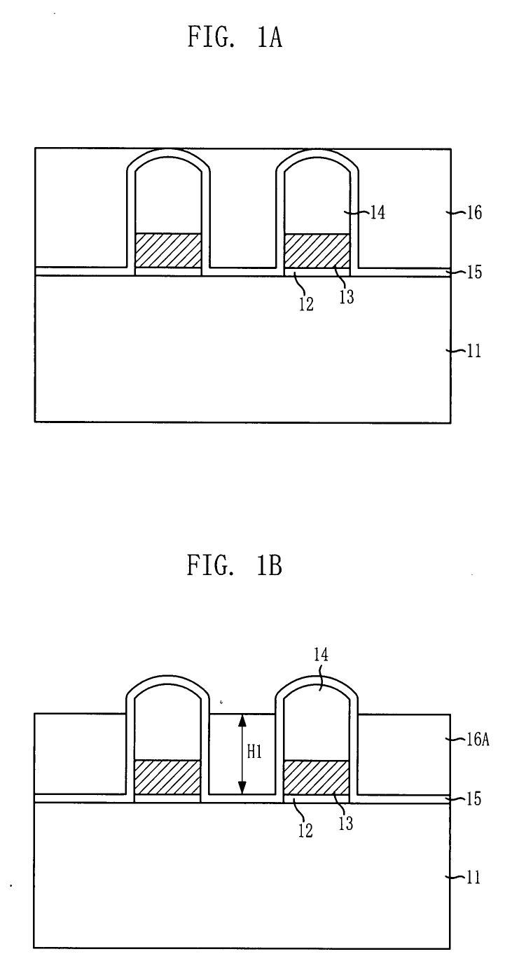

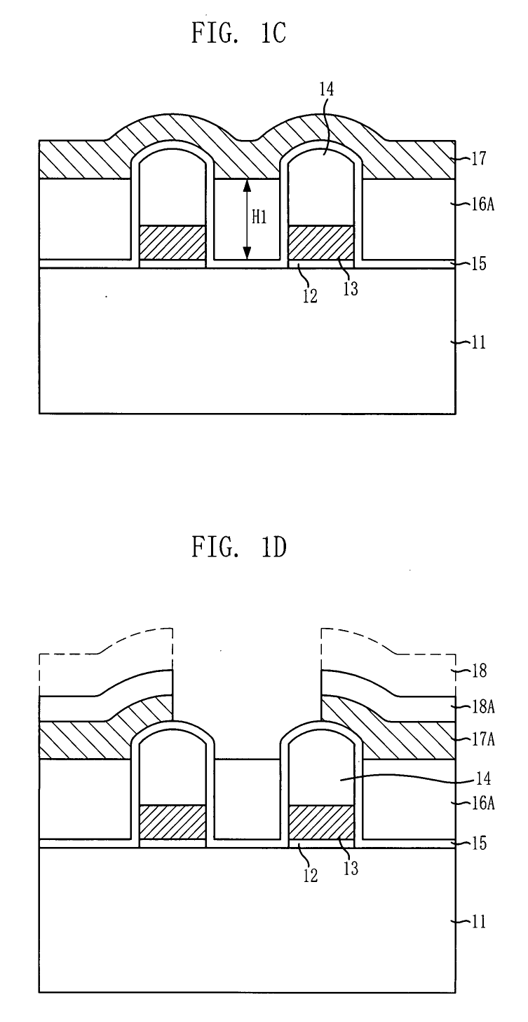

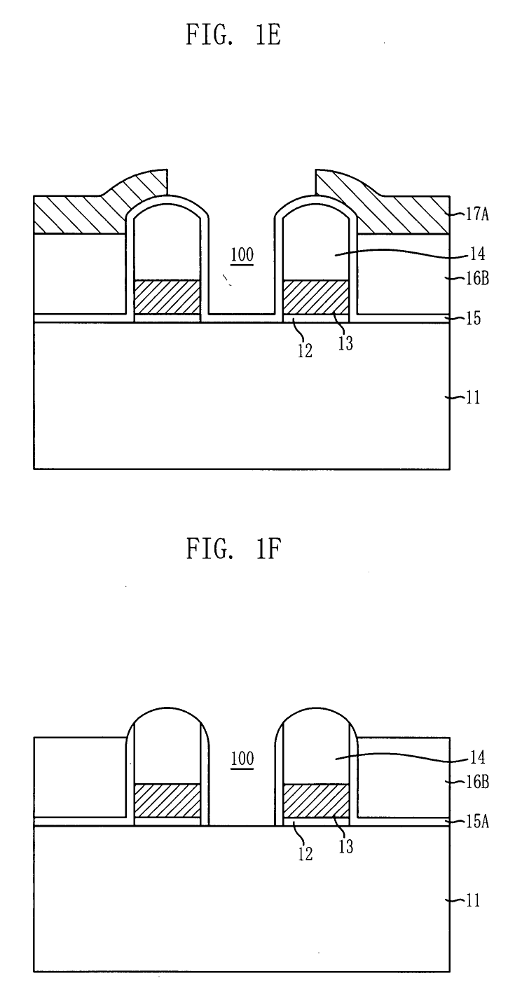

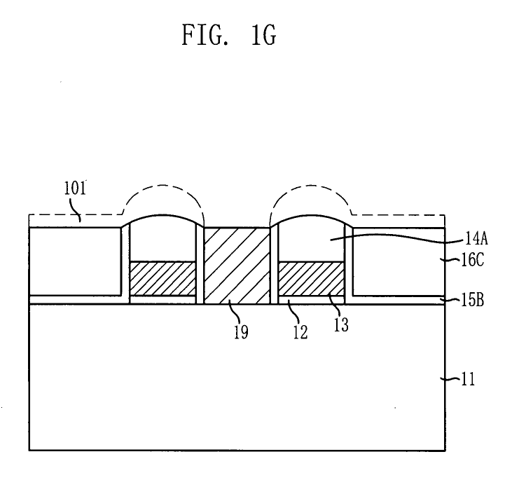

FIGS. 1A to 1G illustrate cross-sectional views of a semiconductor device during a method for fabricating the semiconductor device in accordance with a first embodiment of the present invention.

Referring to FIG. 1A, a plurality of gate patterns are formed over a substrate 11. At this time, the gate patterns are formed in a line type structure, each including a gate oxide layer 12, a gate electrode 13, and a gate hard mask 14. The gate electrode 13 may include polysilicon or a stack structure configured with polysilicon and tungsten. The gate hard mask 14 includes a nitride-based layer.

An etch barrier layer 15 is formed over the resultant structure. The etch barrier layer 15 includes a nitride-based layer. The etch barrier layer 15 functions as an etch barrier during a subsequent landing plug contact etching process using a self-aligned contact (SAC) etch process. Thus, the nitride-based layer used as the etch barrier layer 15 may be referred to as a ‘LPC nitride layer.’

A polished insulation layer (ILD) 16 is formed over the etch barrier layer 15 to fill gaps between the gate patterns. The polished insulation layer 16 is formed by performing a chemical mechanical polish (CMP) process on an insulation layer. The CMP process stops at an upper portion of the gate patterns. Such process is referred to as an ‘ILD CMP process.’ For instance, the CMP process stops at a surface of the etch barrier layer 15. When the etch barrier layer 15 is polished, the CMP process stops at the gate hard mask 14. The polished insulation layer 16 includes an oxide-based material. For instance, the polished insulation layer 16 includes borophosphosilicate glass (BPSG), phosphosilicate glass (PSG), or tetraethyl orthosilicate (TEOS).

Referring to FIG. 1B, a portion of the polished insulation layer 16 is recessed in a manner that the upper portion and sidewall portions of the gate patterns protrude from the substrate structure. An etch process for recessing the polished insulation layer 16 includes performing a wet etch process or a dry etch process. The wet etch process is performed in-situ or ex-situ using a diluted hydrogen fluoride (HF) solution or buffered oxide etchant (BOE). The diluted HF solution comprises HF and water (H₂O). The BOE comprises HF and NF₄F. The dry etch process is performed using a gas which can etch oxide since the polished insulation layer 16 includes an oxide-based layer. For instance, the dry etch process uses a gas including tetrafluoromethane (CF₄) and oxygen (O₂).

The remaining portion of the polished insulation layer 16 is referred to as a remaining insulation layer 16A. The remaining insulation layer 16A remains between the gate patterns, having a certain height ‘H1’. The height ‘H1’ of the remaining insulation layer 16A is greater than that of a contact surface between the gate electrode 13 and the gate hard mask 14.

That is, the remaining insulation layer 16A remains with a thickness that is larger than that obtained after a subsequent CMP process is performed to form a subsequent landing plug. The remaining insulation layer 16A remains with such thickness such that short-circuit between adjacent landing plugs may not occur after the CMP process for forming the landing plugs is performed.

An etch target of the remaining insulation layer 16A to be etched during a subsequent SAC etch process is reduced by the aforementioned etch process for recessing the insulation layer 16. Thus, a thickness of the gate hard mask 14 may not have to be increased. In more detail, a gate hard mask is generally formed with a sufficiently large thickness before performing a landing plug contact formation process, in consideration of a loss of the gate hard mask that generally occurs during the landing plug contact formation process. However, if an etch target of an insulation layer is decreased, the thickness of the gate hard mask may not have to be increased.

Referring to FIG. 1C, a hard mask 17 is formed to fill gaps generated by the remaining insulation layer 16A between the gate patterns. The hard mask 17 includes a material having a sufficient selectivity between nitride and oxide. For instance, the hard mask 17 includes amorphous carbon or a photoresist layer including silicon (Si). When the hard mask 17 includes an amorphous carbon layer, a silicon oxynitride (SiON) layer having an etch selectivity may be formed over the amorphous carbon layer. Also, an oxide-based layer may be formed over the amorphous carbon layer instead of the SiON layer. The oxide-based layer may include a TEOS layer.

The hard mask 17 is formed to be used during a subsequent landing plug contact etch process. Thus, the hard mask 17 may be referred to as a ‘LPC hard mask’. Meanwhile, a planar organic bottom anti-reflective coating (OBARC) layer may further be formed for uniformity when irregularity exists at an upper portion of the hard mask 17.

Referring to FIG. 1D, a photoresist layer is formed over the hard mask 17. A photo-exposure and developing process using a photo mask is performed to form a photoresist pattern 18. The photoresist pattern 18 is referred to as an LPC mask, and is a mask for defining a bar type or a trench type contact hole. For instance, the photoresist pattern 18 is a bar type contact mask.

A landing plug contact etch process is performed using the photoresist pattern 18. The landing plug contact etch process applies a SAC etch method as described earlier. The landing plug contact etch process includes etching the hard mask 17. At this time, the hard mask 17 is etched under an etch condition having a sufficient selectivity between nitride and oxide. Consequently, a portion of the hard mask 17 formed between the gate patterns is etched.

Accordingly, a hard mask pattern 17A mirroring the shape of the photoresist pattern 18 is formed. Portions of the photoresist pattern 18 are removed while etching the hard mask 17. The remaining portions of the photoresist pattern 18 are referred to as a remaining photoresist pattern 18A.

Referring to FIG. 1E, a portion of the remaining insulation layer 16A between the gate patterns is etched. The etch target is decreased since the height of the remaining insulation layer 16A was reduced beforehand by performing the etch process for recessing the insulation layer 16 in FIG. 1B. Thus, it becomes easier to remove the portions of the remaining insulation layer 16A. In particular, undesirable events such as a not-open event of a contact hole may not occur because the remaining insulation layer 16A is decreased in height beforehand by the etch process. Reference numeral 16B refers to an insulation pattern 16B.

The remaining photoresist pattern 18A is removed while etching the portion of the remaining insulation layer 16A. Thus, the hard mask pattern 17A functions as an etch barrier layer when etching the portion of the remaining insulation layer 16A. The etching of the portion of the remaining insulation layer 16A stops at the etch barrier layer 15. Consequently, a contact hole 100 is formed by the aforementioned series of processes.

Referring to FIG. 1F, the hard mask pattern 17A is removed. At this time, the hard mask pattern 17A is easily removed by a removal process using oxygen because the hard mask pattern 17A includes amorphous carbon having a property similar to photoresist.

A portion of the etch barrier layer 15 is etched to expose a portion of the substrate 11 between the gate patterns. Thus, a bottom surface of the contact hole 100 where a landing plug will be formed, that is, the portion of the substrate 11, is exposed. Meanwhile, the etch barrier layer 15 is etched using an etch-back process. Reference numeral 15A refers to a remaining etch barrier layer 15A.

Referring to FIG. 1G, a conductive layer is formed to fill gaps between the gate patterns. An etch-back process or a CMP process is performed to form a landing plug contact 19. The landing plug contact 19 includes a polysilicon layer. The etch-back process or the CMP process also removes portions of the gate hard masks 14 and the insulation pattern 16B. The gate hard masks 14 can be removed during the etch-back process or the, CMP process because the landing plug contact etch process has been performed. Reference numeral 101 refers to a profile of the insulation pattern 16B and the gate patterns before the etch-back process or the CMP process is performed. Reference numerals 16C, 15B, and 14A refer to an etched insulation pattern 16C, an etched etch barrier layer 15B, and an etched gate hard mask 14A, respectively.

According to the first embodiment, the thickness of the insulation layer needed during the landing plug contact etch process is reduced. Such decreased thickness allows a decrease in an aspect ratio, resulting in a reduced etch target and prevention of undesirable events in a device such as a not-open event.

Furthermore, the reduced etch target of the insulation layer decreases a loss of the gate hard mask during a SAC etch process. Thus, the height of the gate hard mask may be additionally decreased, and consequently, the height of the gate patterns may be decreased.

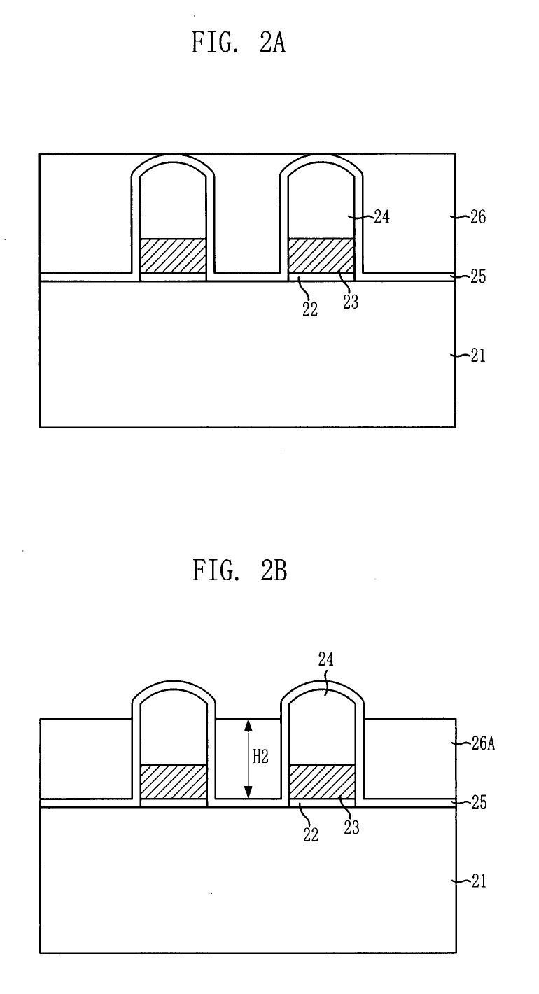

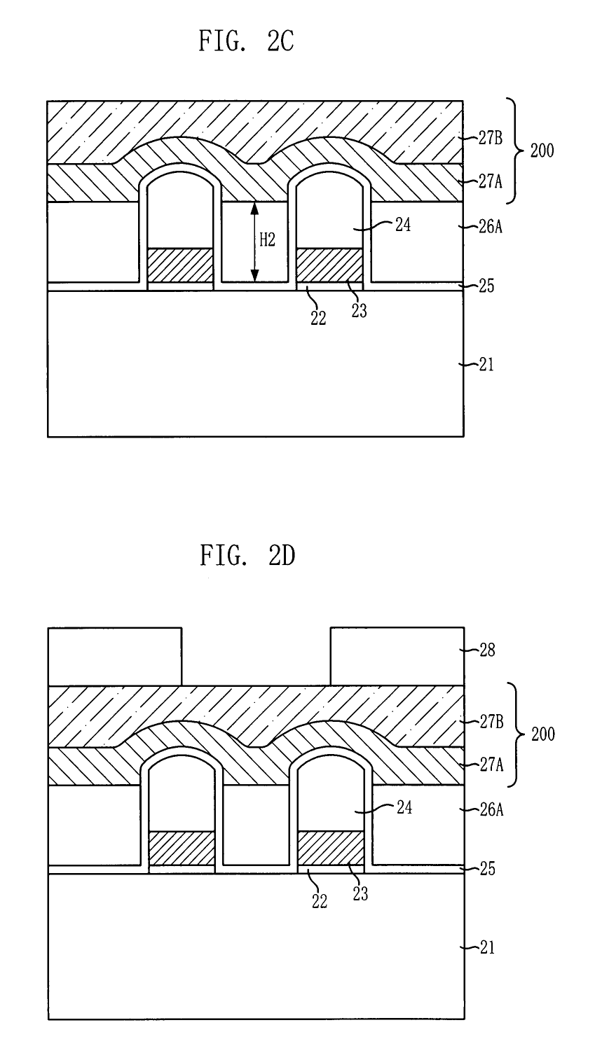

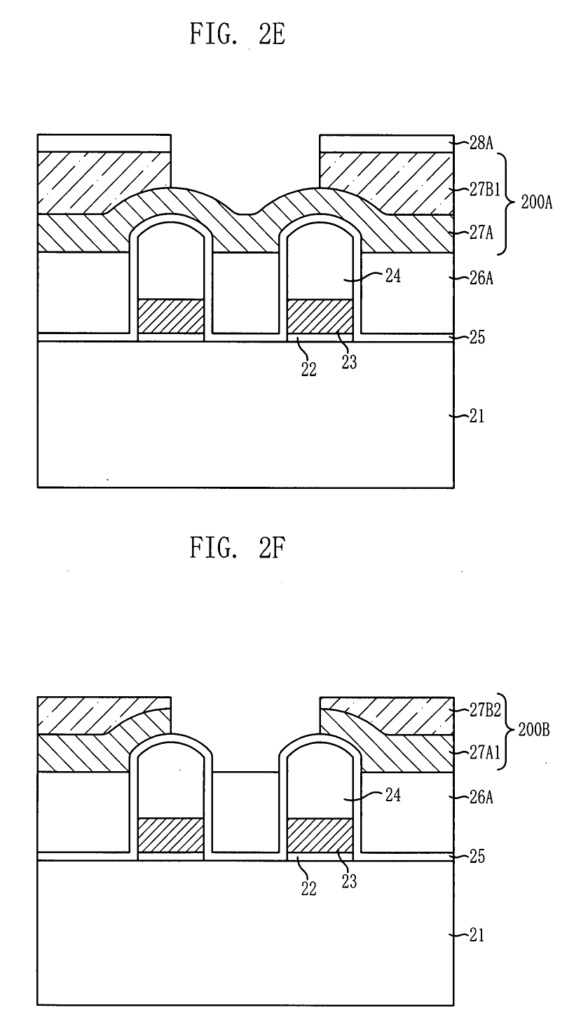

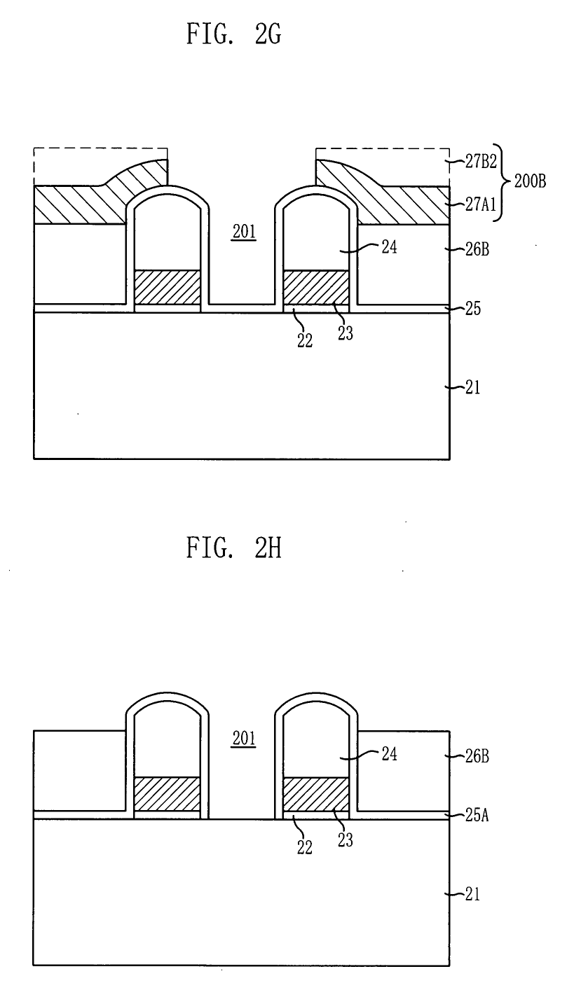

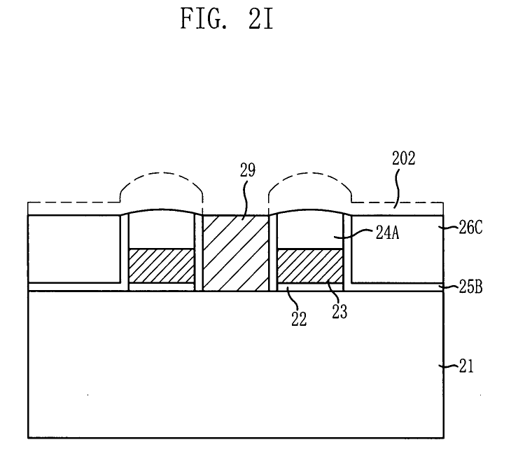

FIGS. 2A to 2I illustrate cross-sectional views of a semiconductor device during a method for fabricating the semiconductor device in accordance with a second embodiment of the present invention.

Referring to FIG. 2A, a plurality of gate patterns are formed over a substrate 21. At this time, the gate patterns are formed in a line type structure, each including a gate oxide layer 22, a gate electrode 23, and a gate hard mask 24. The gate electrode 23 may include polysilicon, a stack structure configured with polysilicon and tungsten, or another stack structure configured with polysilicon and tungsten silicide. The gate hard mask 24 includes a nitride-based layer. The gate hard mask 24 is also referred to as the gate hard mask nitride-based layer.

An etch barrier layer 25 is formed over the resultant structure. The etch barrier layer 25 includes a nitride-based layer. The etch barrier layer 25 functions as an etch barrier during a subsequent landing plug contact etching process using a self-aligned contact (SAC) etch process. Thus, the nitride-based layer used as the etch barrier layer 25 may be referred to as a ‘LPC nitride layer.’

A polished insulation layer (ILD) 26 is formed over the etch barrier layer 25 to fill gaps between the gate patterns. The polished insulation layer 26 is formed by performing a chemical mechanical polish (CMP) process on an insulation layer. The CMP process stops at an upper portion of the gate patterns. Such process is referred to as an ‘ILD CMP process.’ For instance, the CMP process stops at a surface of the etch barrier layer 25. When the etch barrier layer 25 is polished, the CMP process stops at the gate hard mask 24. The polished insulation layer 26 includes an oxide-based material. For instance, the polished insulation layer 26 includes borophosphosilicate glass (BPSG), phosphosilicate glass (PSG), or tetraethyl orthosilicate (TEOS). The ‘ILD CMP process’ applies a slurry having a selectivity between the nitride-based layers, i.e., the etch barrier layer 25 and the gate hard mask 24, and the oxide-based layer, i.e., the polished insulation layer 26, to expose nitride-based materials.

Referring to FIG. 2B, a portion of the polished insulation layer 26 is recessed in a manner that the upper portion and sidewall portions of the gate patterns protrude from the substrate structure. An etch process for recessing the polished insulation layer 26 includes performing a wet etch process or a dry etch process. The wet etch process is performed in-situ or ex-situ using a diluted hydrogen fluoride (HF) solution or buffered oxide etchant (BOE). The diluted HF solution comprises HF and water (H₂0). The BOE comprises HF and NF₄F. Meanwhile, although the gate patterns may be damaged when the wet etch process is applied, the gate patterns are not damaged because the etch barrier layer 25 including a nitride-based layer exists. The nitride-based layer is not etched away during the wet etch process for etching oxide. The dry etch process is performed using a gas which can etch oxide with a high selectivity since the polished insulation layer 26 includes an oxide-based layer. For instance, the dry etch process uses a gas including tetrafluoromethane (CF₄) and oxygen (O₂).

The remaining portion of the polished insulation layer 26 is referred to as a remaining insulation layer 26A. The remaining insulation layer 26A remains between the gate patterns, having a certain height ‘H2’. The height ‘H2’ of the remaining insulation layer 26A is higher than a contact surface between the gate electrode 23 and the gate hard mask 24.

That is, the remaining insulation layer 26A remains with a thickness that is larger than a subsequent thickness to be obtained after a subsequent CMP process is performed to form a subsequent landing plug. The remaining insulation layer 26A remains with such thickness such that short-circuit between adjacent landing plugs may not occur after the CMP process for forming the landing plugs is performed.

An etch target of the remaining insulation layer 26A to be etched during a subsequent SAC etch process is reduced by the aforementioned etch process for recessing the polished insulation layer 26. Thus, a thickness of the gate hard mask 24 may not have to be increased. In more detail, a gate hard mask is generally formed with a sufficiently large thickness before performing a landing plug contact formation process in consideration of a loss of the gate hard mask generally occurring during the landing plug contact formation process. Consequently, a thickness increase is often generated. However, if an etch target of an insulation layer is decreased, the thickness of the gate hard mask may not have to be increased.

Referring to FIG. 2C, a first hard mask 27A is formed to fill gaps generated by the remaining insulation layer 26A between the gate patterns. At this time, the first hard mask 27A includes a material having a high selectivity between the gate hard mask 24 and the etch barrier layer 25, including a nitride-based layer, and the remaining insulation layer 26A, including an oxide-based layer. For instance, the first hard mask 27A may include amorphous carbon or spin on carbon (SOC). The first hard mask 27A includes a material containing carbon. Consequently, the first hard mask 27A obtains a sufficient selectivity between oxide and nitride and thus may function as a hard mask.

A second hard mask 27B is formed over the first hard mask 27A. The second hard mask 27B includes an organic matter including silicon (Si). For instance, the second hard mask 27B includes a photoresist layer including silicon. The photoresist layer including silicon functions as an anti-reflective coating layer and a hard mask. Also, a selectivity ascending effect may be obtained because the silicon is included, unlike a typical photoresist layer.

The photoresist layer including silicon has a sufficient level of fluid characteristic. Thus, the photoresist layer including silicon can lessen a surface irregularity generated on the first hard mask 27A formed below the second hard mask 27B. At this time, the second hard mask 27B is formed to a thickness ranging from approximately 200 Å to approximately 1,500 Å such that a height difference generated by the surface profile of the first hard mask 27A is reduced. Thus, SiON or TEOS layers, typically needed when forming the first hard mask 27A including amorphous carbon, may no longer be needed when the second hard mask 27B comprising the photoresist layer including silicon is formed. Consequently, the process is simplified.

The photoresist layer including silicon used as the second hard mask 27B may be formed using a track apparatus of a typical lithography process. Thus, a subsequent organic bottom anti-reflective coating (OBARC) layer formation process and mask process may be performed collectively.

As a result, a hard mask 200 configured with the first hard mask 27A and the second hard mask 27B obtains a planarized surface without surface irregularity. The hard mask 200 functions as a hard mask during a subsequent landing plug contact etch process. Thus, the hard mask 200 may be referred to as a ‘LPC hard mask.’

Referring to FIG. 2D, a photoresist layer is formed over the hard mask 200. A photo-exposure and developing process using a photo mask is performed to form a photoresist pattern 28. The photoresist pattern 28 is referred to as a landing plug contact mask. It is easy to perform the photo-exposure process for forming the photoresist pattern 28 because a surface of the hard mask 200 is planarized. Meanwhile, an OBARC layer may be further applied for uniformity before forming the photoresist pattern 28 when surface irregularity exists on the hard mask 200.

Referring to FIGS. 2E and 2F, the hard mask 200 is etched using the photoresist pattern 28. At this time, the hard mask 200 is etched under a certain condition having a sufficient selectivity between nitride and oxide such that a portion of the hard mask 200 formed between the gate patterns is etched. Accordingly, a hard mask pattern 200B (FIG. 2F) mirroring the shape of the photoresist pattern 28 is formed.

In more detail, a portion of the photoresist pattern 28 is removed while etching the second hard mask 27B of the hard mask 200. Reference numerals 28A, 27B1, and 200A refer to a remaining photoresist pattern 28A, an etched second hard mask 27B1, and an etched hard mask 200A, respectively. The remaining photoresist pattern 28A is removed when the first hard mask 27A is etched. Also, a portion of the etched second hard mask 27B1 is removed while etching the first hard mask 27A. Reference numerals 27B2 and 27A1 refer to a remaining second hard mask 27B2 and a remaining first hard mask 27A1, respectively.

Referring to FIG. 2G, the remaining insulation layer 26A is etched after forming the hard mask pattern 200B by etching the hard mask 200. That is, a portion of the remaining insulation layer 26A formed between the gate patterns is etched. This etch target has been made smaller, since the height of the remaining insulation layer 26A was reduced beforehand by performing the etch process for recessing the insulation layer 26 in FIG. 2B. Thus, it becomes easier to remove the remaining insulation layer 26A. In particular, undesirable events such as a not-open event of a contact hole may not occur because the remaining insulation layer 26A is decreased in height beforehand by the etch process. Reference numeral 26B refers to an insulation pattern 26B.

The remaining first hard mask 27A1 functions as an etch barrier layer even if the remaining second hard mask 27B2 is removed while etching the remaining insulation layer 26A. A dotted line represents removal of the remaining second hard mask 27B2. The etching of the remaining insulation layer 26A stops at the etch barrier layer 25. Consequently, a contact hole 201 is formed by the aforementioned series of processes.

Referring to FIG. 2H, the remaining portions of the hard mask pattern 200B are removed. For instance, the remaining first hard mask 27A1 is removed. At this time, the remaining first hard mask 27A1 is easily removed by a removal process using oxygen because the remaining first hard mask 27A1 includes amorphous carbon having a property similar to photoresist. Even if the remaining second hard mask 27B2 remains, the remaining second hard mask 27B2 is easily removed by oxygen because the remaining second hard mask 27B2 includes photoresist.

The etch barrier layer 25 is selectively etched to expose a portion of the substrate 21 between the gate patterns. Thus, a bottom surface of the contact hole 201 where a landing plug will be formed, that is, the portion of the substrate 21, is exposed. Meanwhile, the etch barrier layer 25 is etched using an etch-back process. Reference numeral 25A refers to a remaining etch barrier layer 25A.

Referring to FIG. 2I, a conductive layer is formed to fill gaps between the gate patterns. An etch-back process or a CMP process is performed to form a landing plug contact 29. The landing plug contact 29 includes a polysilicon layer. The etch-back process or the CMP process also removes portions of the gate hard masks 24 and the insulation pattern 26B. The gate hard masks 24 may be removed during the etch-back process or the CMP process because the landing plug contact etch process has been performed. Reference numeral 202 refers to a profile of the insulation pattern 26B and the gate patterns before the etch-back process or the CMP process is performed. Reference numerals 26C, 25B, and 24A refer to an etched insulation pattern 26C, an etched etch barrier layer 25B, and an etched gate hard mask 24A, respectively.

According to the second embodiment, the thickness of the insulation layer needed during the landing plug contact etch process is reduced. Such decreased thickness allows a decrease in an aspect ratio, resulting in a reduced etch target and prevention of undesirable events in a device such as a not-open event.

Furthermore, the reduced etch target of the insulation layer decreases a loss of the gate hard mask during a SAC etch process. Thus, the height of the gate hard mask may be additionally decreased, and consequently, the height of the gate patterns may be decreased.

Moreover, the second embodiment omits formation processes for additional insulation layers such as a SiON layer and a plasma enhanced tetraethyl orthosilicate (PETEOS) layer, unlike the first embodiment requiring formation processes for forming additional insulation layers. Such layers are generally formed for patterning when using an amorphous carbon hard mask. Thus, the process may be simplified. Also, the second embodiment uses the photoresist layer including silicon having a sufficient level of fluid characteristic as the second hard mask. Thus, a hard mask structure is formed, which can alleviate surface irregularity generated by the etch process for recessing the insulation layer.

Meanwhile, in the first embodiment, amorphous carbon having a sufficient step coverage characteristic is used as the hard mask such that the differences in height generated by the recessed insulation layer is mirrored. Thus, it is difficult to perform the subsequent lithography process. However, in the second embodiment, the second hard mask having a sufficient level of fluid characteristic is additionally applied to alleviate the differences in height generated by the recessed insulation layer.

The embodiments of the present invention may be applied to bit line contact or storage node contact processes, which are known to be similar to the landing plug contact process.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
forming an etch barrier layer over a semi-finished substrate that includes a plurality of patterns;
forming an insulation layer over the etch barrier layer;
planarizing the insulation layer;
recessing a portion of the planarized insulation layer;
forming a hard mask pattern over the recessed and planarized insulation layer;
etching the recessed insulation layer to form a contact hole;
etching the etch barrier layer formed over a bottom portion of the contact hole; and
forming a plug contact in the contact hole.

2. The method of claim 1, wherein the hard mask pattern includes a material with a fluid characteristic and wherein etching the recessed insulation layer to form the contact hole comprises using a self-aligned contact (SAC) etch process.

3. The method of claim 1, wherein forming the hard mask pattern comprises:
forming a first hard mask over the recessed and planarized insulation layer;
forming a second hard mask over the first hard mask, the second hard mask having a fluid characteristic;
forming a photoresist pattern over the second hard mask;
etching the second hard mask; and
etching the first hard mask.

4. The method of claim 3, wherein the first hard mask comprises a material having selectivity to the insulation layer, and the second hard mask comprises an organic matter including silicon.

5. The method of claim 4, wherein the first hard mask comprises amorphous carbon or spin on carbon.

6. The method of claim 4, wherein the second hard mask comprises a photoresist layer including silicon.

7. The method of claim 6, wherein the second hard mask is formed to a thickness ranging from approximately 200 Å to approximately 1,500 Å.

8. The method of claim 1, wherein the recessed insulation layer has a height greater than a height of the contact surface between a gate electrode and gate hard mask.

9. The method of claim 1, wherein the recessed insulation layer has a height greater than a height of the remaining insulation layer when forming the plug contact.

10. The method of claim 1, wherein recessing the portion of the planarized insulation layer comprises performing a wet etch or dry etch process.

11. The method of claim 1, further comprising, before etching the etch barrier layer formed over the bottom portion of the contact hole, removing the hard mask pattern remaining after the contact hole is formed.

12. The method of claim 1, wherein forming the plug contact comprises:
forming a conductive layer over the substrate structure that fills in the contact hole; and
removing portions of the conductive layer to form landing plug contacts isolated from each other.

13. The method of claim 12, wherein the conductive layer comprises polysilicon.

14. The method of claim 12, wherein removing the portions of the conductive layer comprises performing an etch-back process or a chemical mechanical polish (CMP) process.

15. The method of claim 12, wherein the plug contact is selected from the group consisting of a landing plug contact, a bit line contact, and a storage node contact.

16. The method of claim 1, wherein the etch barrier layer comprises a nitride-based layer, the insulation layer comprises an oxide-based layer, and the patterns comprise gate patterns including a gate hard mask nitride-based layer.

17. The method of claim 16, wherein recessing the portion of the planarized insulation layer comprises recessing the portion of the planarized insulation layer in-situ or ex-situ using a diluted hydrogen fluoride (HF) solution or a buffered oxide etchant (BOE).
